(19) United States
(12) Patent Application Publication
(10) Pub. No.: US 2025/0344571 A1
(43) Pub. Date: Nov. 6, 2025

(54) LIGHT-EMITTING ELEMENT, DISPLAY DEVICE, AND METHOD FOR MANUFACTURING LIGHT-EMITTING ELEMENT

(71) Applicant: Sharp Display Technology Corporation, Kameyama City, Mie (JP)

(72) Inventors: Sumire HOMBO, Kameyama City, Mie (JP); Kaoru ABE, Kameyama City, Mie (JP); Atsushi KOUMURA, Kameyama City, Mie (JP)

(21) Appl. No.: 18/862,266

(22) PCT Filed: Jun. 28, 2022
(86) PCT No.: PCT/JP2022/025677

§ 371 Date: Nov. 1, 2024

(51) Int. Cl. H10K 50/854; H10K 50/84; H10K 59/122; H10K 59/126; H10K 59/35; H10K 59/80; H10K 71/60

(52) U.S. Cl. CPC H10K 50/854; H10K 50/841; H10K 59/122; H10K 59/126; H10K 59/871; H10K 59/877; H10K 71/60; H10K 59/35

(57) ABSTRACT

A light-emitting element includes a first electrode, a light-emitting layer located in an upper layer with respect to the first electrode, a second electrode located in an upper layer with respect to the light-emitting layer, a bank that is located in an upper layer with respect to the second electrode and has insulating properties, and a light diffusion layer located in the bank.

### TECHNICAL FIELD

The disclosure relates to a light-emitting element, a display device, and a method for manufacturing a light-emitting element.

BACKGROUND ART

PTL 1 discloses a method of disposing a scattering film on the outermost surface on the light emission side of an organic EL light-emitting device.

### CITATION LIST

### Patent Literature

PTL 1: JP 6309271 B

### SUMMARY

### Technical Problem

Known light-emitting devices have a problem in that a color mixing phenomenon is likely to occur in some applications in which light of a plurality of colors is emitted (for example, display devices).

### Solution to Problem

A light-emitting element according to an aspect of the disclosure includes a first electrode, a light-emitting layer located in an upper layer with respect to the first electrode, a second electrode located in an upper layer with respect to the light-emitting layer, a bank located in an upper layer with respect to the second electrode, the bank having insulating properties, and a light diffusion layer located in the bank.

### Advantageous Effects of Disclosure

According to an aspect of the disclosure, since each light-emitting element includes a light diffusion layer, it is possible to suppress a color mixing phenomenon between the light-emitting elements while improving viewing angle characteristics.

### BRIEF DESCRIPTION OF DRAWINGS

FIG. 1 is a cross-sectional view illustrating a configuration of a light-emitting element according to the present embodiment.

FIG. 2 is a cross-sectional view illustrating another configuration of the light-emitting element according to the present embodiment.

FIG. 3 is a cross-sectional view illustrating another configuration of the light-emitting element according to the present embodiment.

FIG. 4 is a cross-sectional view illustrating another configuration of the light-emitting element according to the present embodiment.

FIG. 5 is a flowchart illustrating a manufacturing method for the light-emitting element according to the present embodiment.

FIG. 6 is a cross-sectional view illustrating the manufacturing method for the light-emitting element according to the present embodiment.

FIG. 7 is a schematic diagram illustrating a configuration of a display device according to the present embodiment.

FIG. 8 is a cross-sectional view illustrating a configuration of the display device according to the present embodiment.

FIG. 9 is a plan view illustrating a configuration of the display device according to the present embodiment.

### DESCRIPTION OF EMBODIMENTS

### Light-Emitting Element

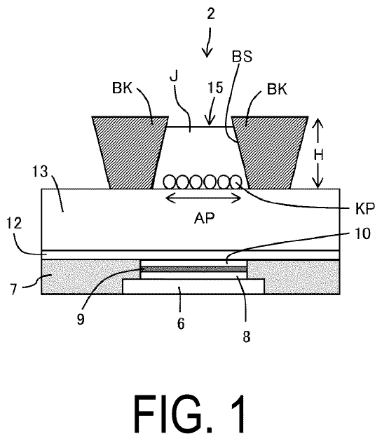

FIG. 1 is a cross-sectional view illustrating a configuration of a light-emitting element according to the present embodiment. As illustrated in FIG. 1, a light-emitting element 2 includes a first electrode 6, a light-emitting layer 9 located in an upper layer with respect to the first electrode 6, a second electrode 12 located in an upper layer with respect to the light-emitting layer 9, a sealing layer 13 located in an upper layer with respect to the second electrode 12, a bank BK that is located in an upper layer with respect to the sealing layer 13 and has insulating properties, and a light diffusion layer 15 located in the bank BK. “Located in an upper layer” means, for example, being formed in a step after that of a target object. Hereinafter, visual recognition (including see-through) by a line of sight parallel to the normal line of the first electrode 6 may be referred to as a “plan view”.

Since the light-emitting element 2 of the present embodiment includes the light diffusion layer 15, it is possible to suppress the color mixing phenomenon between light-emitting elements in application to a device (for example, a display device to be described later) including a plurality of light-emitting elements having different emission colors while improving the viewing angle characteristics of the light-emitting element 2 (for example, reducing a color shift at an oblique viewing angle). In addition, since the bank BK has insulating properties, a parasitic capacitance is not formed between the bank BK and the second electrode 12, and the potential of the second electrode 12 can be stabilized.

The light-emitting element 2 may include the sealing layer 13 located between the second electrode 12 and the bank BK. In this case, the durability of the light-emitting layer 9 can be enhanced. A charge function layer 8 may be provided between the first electrode 6 and the light-emitting layer 9, and a charge function layer 10 may be provided between the light-emitting layer 9 and the second electrode 12. An edge cover film 7 may be provided to cover the edge of the first electrode 6. The edge cover film 7 has an opening that exposes a non-edge portion of the first electrode 6.

The light diffusion layer 15 may include a plurality of light diffusion particles KP. This facilitates the formation of the light diffusion layer 15. The plurality of light diffusion particles KP may be located on the bottom surface of the light diffusion layer 15, or the sealing layer 13 and the light diffusion layer 15 may be in contact with each other. In this way, the distance between the light-emitting layer 9 and the plurality of light diffusion particles KP is reduced, and the color mixing phenomenon between the light-emitting elements can be further suppressed.

The bottom surface of the light diffusion layer 15 includes a particle arrangement region AP in which the plurality of light diffusion particles KP are located, and the entire particle arrangement region AP overlaps the light-emitting layer 9 in a plan view. By limiting the range of the particle arrangement region AP in this way, the above-described color mixing phenomenon can be suppressed more effectively.

The light diffusion layer 15 may have a shape in which the upper surface is smaller than the bottom surface, and the bank BK may have an inverse tapered shape in which the bank side surface BS is overhanging. In this way, the light diffusion particles KP are less likely to be disposed on the bank side surface BS, and the above-described color mixing phenomenon can be more effectively suppressed.

In a plan view, the entire upper surface of the light diffusion layer 15 may overlap the light-emitting layer 9. By limiting the range of the upper surface of the light diffusion layer 15 in this way, the above-described color mixing phenomenon can be suppressed more effectively.

The light diffusion layer 15 may include a light-transmitting resin J (for example, a transparent resin) covering the plurality of light diffusion particles KP, and the bank BK may have liquid repellency. A height H of the bank BK may be greater than the height of the light diffusion layer 15. In this way, the light diffusion layer 15 can be easily formed by coating. Each of the plurality of light diffusion particles KP included in the light diffusion layer 15 may be transparent, and the refractive index of each light diffusion particle KP may be different from the refractive index of the resin J. In this way, the amount of light emitted upward is increased, and the light extraction efficiency is improved.

The first electrode 6 may be a light-reflecting electrode, and the second electrode 12 may be a light-transmitting electrode. Thus, a top emission structure having a high light extraction efficiency can be obtained. Alternatively, the first electrode 6 may be an anode, and the second electrode 12 may be a cathode. In this case, the first charge function layer 8 may be a hole transport layer, the second charge function layer 10 may be an electron transport layer. The holes and electrons recombine inside the light-emitting layer 9 due to a drive current between the first electrode 6 and the second electrode 12, and light is emitted when the excitons generated in this manner transition to a ground state.

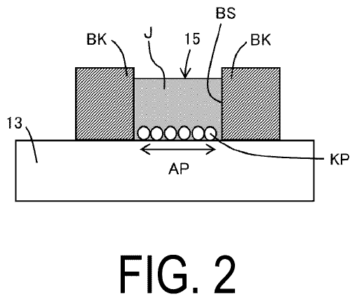

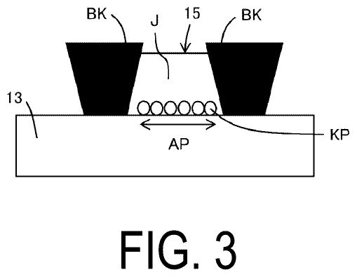

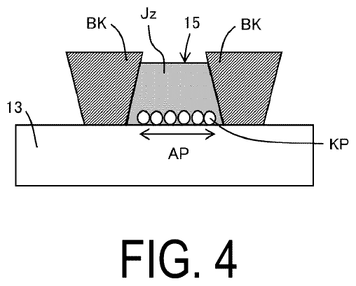

FIG. 2 is a cross-sectional view illustrating another configuration of the light-emitting element according to the present embodiment. In FIG. 1, the bank side surface BS overhangs the upper surface of the sealing layer 13, but no such limitation is intended. As illustrated in FIG. 2, the side surface BS of the bank BK may have a shape perpendicular to the upper surface of the sealing layer 13. This facilitates the formation of the bank BK. FIG. 3 is a cross-sectional view illustrating another configuration of the light-emitting element according to the present embodiment. As illustrated in FIG. 2, the bank BK may have a light shielding property. This makes it possible to more effectively suppress the above-described color mixing phenomenon. FIG. 4 is a cross-sectional view illustrating another configuration of the light-emitting element according to the present embodiment. As illustrated in FIG. 4, a resin Js of the light diffusion layer 15 may have characteristics of absorbing visible light in a predetermined range of wavelengths (for example, 550 nm to 600 nm (yellow colored light) or 480 nm to 520 nm (light blue colored light)). In this way, external light reflection can be reduced.

As the sealing layer 13, an inorganic insulating film such as silicon nitride or silicon oxide can be used. The sealing layer 13 may include an organic insulating film having a planarization function and two inorganic insulating films sandwiching the organic insulating film. A photosensitive fluorine resist can be used for the bank BK.

As the resin J, for example, polymethyl methacrylate (PMMA), polyvinyl alcohol (PVA), polyvinyl chloride (PVC), polycarbonate (PC), polyethylene (PE), polystyrene (PS), polyamide (PA), silicone (SI), urea (UF), epoxy (EP), polypropylene (PP), cellulose acetate (CA), or polyvinylidene chloride (PVDC) can be used.

As the light diffusion particles KP, for example, alumina (aluminum oxide), hollow silica, aluminum, barium sulfate, silicon oxide, titanium oxide, white lead (basic lead carbonate), zinc oxide, zinc, melamine resin, acrylic resin, polystyrene resin, or the like can be used.

As the first electrode 6, for example, a light-reflecting film of Al (aluminum), Ag (silver), Mg (magnesium), or the like can be used. An ultrathin metal film such as an indium tin oxide (ITO) film or a magnesium-silver alloy can be used as the second electrode 12.

### Manufacturing Method for Light-Emitting Element

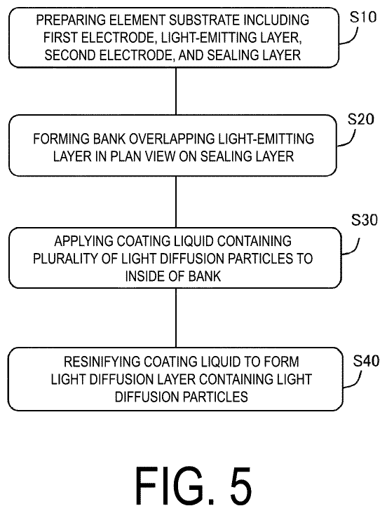

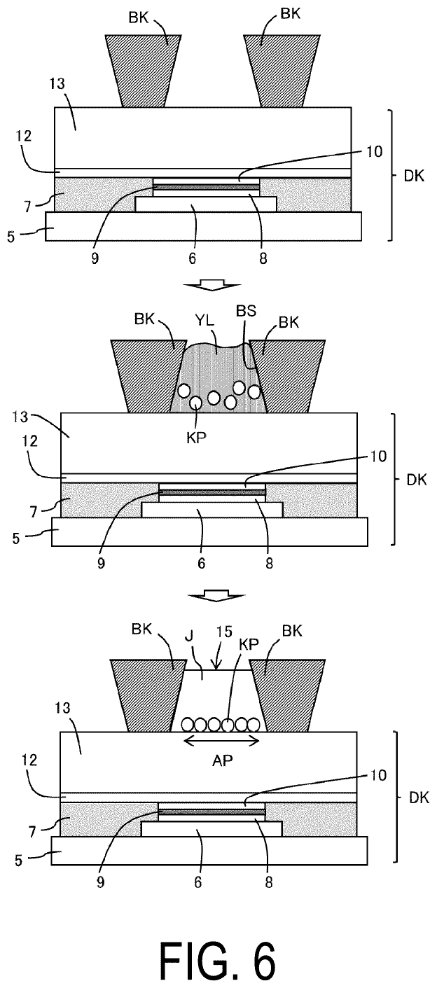

FIG. 5 is a flowchart illustrating a manufacturing method for a light-emitting element according to the present embodiment. FIG. 6 is a cross-sectional view illustrating the manufacturing method for the light-emitting element according to the present embodiment. In the manufacturing method for the light-emitting element illustrated in FIG. 5, the steps of preparing an element substrate DK including the first electrode 6, the light-emitting layer 9, the second electrode 12, and the sealing layer 13, forming the insulating bank BK overlapping the light-emitting layer 9 in a plan view on the sealing layer 13, applying a coating liquid YL containing the plurality of light diffusion particles KP to the inside of the bank BK, and resinifying the coating liquid YL to form the light diffusion layer 15 containing the resin J and the light diffusion particles KP may be performed.

The density of the light diffusion particles KP may be greater than the density of the coating liquid YL. The difference in specific gravity between the light diffusion particles KP and the coating liquid (before curing) and the viscosity of the coating liquid (before curing) are related to the two-layer formation of the light diffusion particles KP and the resin J, and the difference in specific gravity is preferably large and the viscosity of the coating liquid is preferably low. For example, melamine may be used as the light diffusion particles KP, the particle density may be set to 1.5 (g/cm³), the coating liquid density may be set to 0.9 (g/cm³), and the viscosity of the coating liquid may be set to 7.68 (mPa/s). Alternatively, alumina may be used as the light diffusion particles KP, the particle density may be set to 3.9 (g/cm³), the coating liquid density may be set to 1.13 (g/cm³), and the viscosity of the coating liquid may be set to 3.92 (mPa/s).

The bank BK may have an inverse tapered shape in which the bank side surface BS is overhanging. In this way, the light diffusion particles KP in the coating liquid YL fall to the bank bottom surface without staying on the bank side surface BS, and thus it is possible to more effectively suppress the above-described color mixing phenomenon. The bank BK having an inverse tapered shape can be formed by, for example, using a photolithography process (including wet etching), a bank film made of a photosensitive resin or the like.

### Display Device

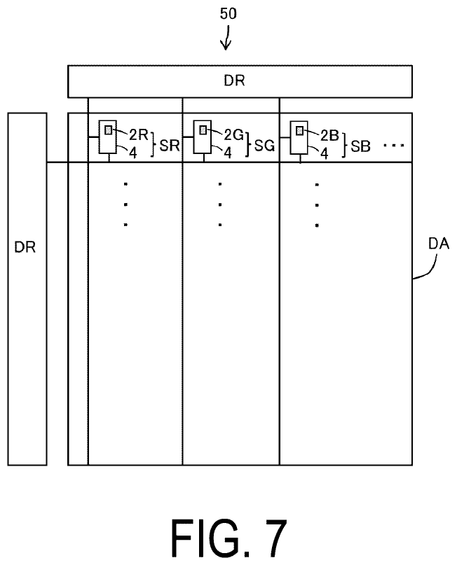

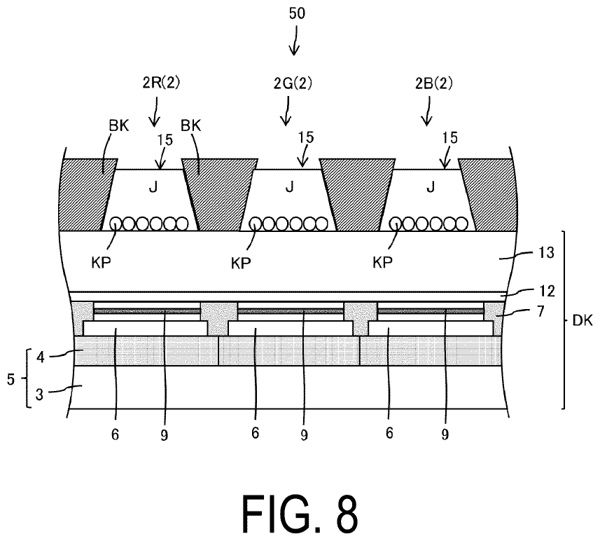

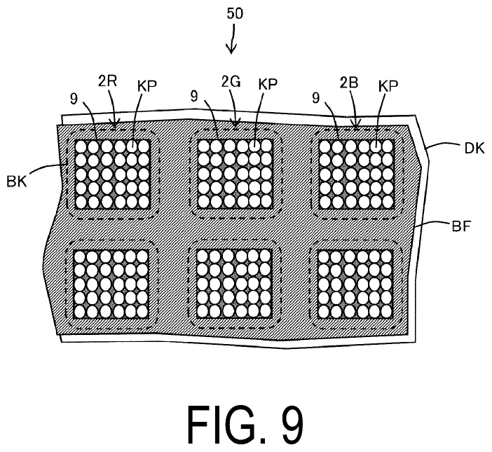

FIG. 7 is a schematic diagram illustrating a configuration of a display device according to the present embodiment. FIG. 8 is a cross-sectional view illustrating a configuration of the display device according to the present embodiment. FIG. 9 is a plan view illustrating a configuration of the display device according to the present embodiment. As illustrated in FIG. 7 to FIG. 9, a display device 50 includes a display portion DA including a plurality of subpixels SR, SG, and SB that emit different colors, and a driver circuit DR that drives the plurality of subpixels SR, SG, and SB, and each of the plurality of subpixels includes the above-described light-emitting element 2 (2R, 2G, 2B).

To be specific, the display device 50 may include a pixel circuit substrate 5 including a main substrate 3 and a pixel circuit layer 4, and the light-emitting element 2R that emits red light, the light-emitting element 2G that emits green light, and the light-emitting element 2B that emits blue light may be formed on the pixel circuit substrate 5. The first subpixel SR may include the pixel circuit 4 and the light-emitting element 2R, the second subpixel SG may include the pixel circuit 4 and the light-emitting element 2G, and the third subpixel SB may include the pixel circuit 4 and the light-emitting element 2B.

As the main substrate 3, a glass substrate or a flexible substrate containing resin such as polyimide as a main component can be used. A barrier layer that acts as a barrier to foreign matters such as water or oxygen may be provided on an upper surface of the main substrate 3. The inversely tapered bank BK of the light-emitting elements 2R, 2G, and 2B can be formed by, for example, a plurality of holes that penetrate the bank film BF and has a shape wider on the bottom side.

Since each of the plurality of light-emitting elements 2 (2R, 2G, and 2B) includes the light diffusion layer 15, the display device 50 has high display quality. That is, the viewing angle characteristics are high (the color shift at the oblique viewing angle is small), and the color mixing phenomenon and the bleeding phenomenon between the subpixels are suppressed.

The embodiments described above are for the purpose of illustration and description and are not intended to be limiting. It will be apparent to those skilled in the art that many variations will be possible in accordance with these examples and descriptions.

1. A light-emitting element comprising:
a first electrode;
a light-emitting layer located in an upper layer with respect to the first electrode;
a second electrode located in an upper layer with respect to the light-emitting layer;
a bank located in an upper layer with respect to the second electrode, the bank having insulating properties; and
a light diffusion layer located in the bank.

2. The light-emitting element according to claim 1, further comprising
a sealing layer located between the second electrode and the bank.

3. The light-emitting element according to claim 1,
wherein the light diffusion layer contains a plurality of light diffusion particles.

4. The light-emitting element according to claim 3,
wherein the plurality of light diffusion particles are located on a bottom surface of the light diffusion layer.

5. The light-emitting element according to claim 4,
wherein a particle arrangement region in which the plurality of light diffusion particles are located is included in a bottom surface of the light diffusion layer, and the entire particle arrangement region overlaps the light-emitting layer in a plan view.

6. The light-emitting element according to any one of claim 1,
wherein the light diffusion layer has a shape in which an upper surface is smaller than a bottom surface.

7. The light-emitting element according to claim 6,
wherein the entire upper surface overlaps the light-emitting layer in a plan view.

8. The light-emitting element according to claim 1,
wherein the bank has an inverse tapered shape in which a bank side surface overhangs.

9. The light-emitting element according to claim 1,
wherein the bank has liquid repellency.

10. The light-emitting element according to claim 1,
wherein the bank has a light shielding property.

11. The light-emitting element according to claim 3,
wherein the light diffusion layer includes a resin that is transparent and covers the plurality of light diffusion particles.

12. The light-emitting element according to claim 11,
wherein each of the plurality of light diffusion particles is transparent.

13. The light-emitting element according to claim 11,
wherein the resin has characteristics of absorbing visible light in a predetermined wavelength range.

14. The light-emitting element according to claim 11,
wherein a refractive index of each light diffusion particle is different from a refractive index of the resin.

15. The light-emitting element according to claim 2,
wherein the sealing layer and the light diffusion layer are in contact with each other.

16. The light-emitting element according to claim 1,
wherein a height of the bank is greater than a height of the light diffusion layer.

17. The light-emitting element according to claim 1,
wherein the first electrode is a light-reflecting electrode, and
the second electrode is a light-transmitting electrode.

18. A display device comprising:
a plurality of subpixels configured to emit different colors,
wherein each of the plurality of subpixels includes the light-emitting element according to claim 1.

19. A method for manufacturing a light-emitting element, the method comprising:
preparing an element substrate including a first electrode, a light-emitting layer, a second electrode, and a sealing layer;
forming a bank on the sealing layer, the bank having insulating properties and overlapping the light-emitting layer in a plan view; and
applying a coating liquid containing a plurality of light diffusion particles to an inside of the bank.

20. The method for manufacturing a light-emitting element according to claim 19, wherein a density of each light diffusion particle is greater than a density of the coating liquid.
